(19) United States
(12) Patent Application Publication
(10) Pub. No.: US 2018/0226021 A1
(43) Pub. Date: Aug. 9, 2018

(54) PIXEL UNIT AND DISPLAY DEVICE

(71) Applicant: Wuhan China Star Optoelectronics Technology Co., Ltd., Wuhan, Hubei (CN)

(72) Inventor: Yufeng Jin, Wuhan, Hubei (CN)

(73) Assignee: Wuhan China Star Optoelectronics Technology Co., Ltd., Wuhan, Hubei (CN)

(21) Appl. No.: 15/326,232

(22) PCT Filed: Dec. 27, 2016
(86) PCT No.: PCT/CN2016/112241

§ 371 Date: Jan. 13, 2017

(30) Foreign Application Priority Data
Jul. 18, 2016 (CN) 201610563495.8

(51) Int. Cl. G09G 3/3233; H05B 33/08; H01L 27/32

(52) U.S. Cl. CPC G09G 3/3233; H01L 27/3213; H01L 27/3265; H05B 33/0896

(57) ABSTRACT

Disclosed are a pixel unit and a display device. The pixel unit includes two sub-pixels of different colors. Each of the sub-pixels is in a regular hexagon shape, and the two sub-pixels share one side. The display device includes two types of the pixel units which include sub-pixels of four different colors of red, green, blue, and white. The pixel unit and the display device can be applied to an OLED display device or other types of display devices.

### CROSS-REFERENCE TO RELATED APPLICATIONS

This application claims the priority of Chinese patent application CN 201610563495.8, entitled “Pixel Unit and Display Device” and filed on Jul. 18, 2016, the entirety of which is incorporated herein by reference.

### FIELD OF THE INVENTION

The present disclosure relates to the technical field of display technology, and in particular, to a pixel unit and a display device.

### BACKGROUND OF THE INVENTION

With the development of display technologies, the organic light emitting diode (OLED) display technology is increasingly mature, and has already been applied widely in various display fields.

An OLED display device drives each sub-pixel through a thin film transistor (TFT). Specifically, each sub-pixel is provided with a thin film transistor so that each sub-pixel can operate independently and not affected by other sub-pixels.

As is shown in FIG. 1, in a conventional OLED display device, each pixel unit consists of three sub-pixels 10 of red (R), green (G), and blue (B), and a pixel array forms an entire display area. As is shown in FIG. 2, in another OLED display device, each pixel unit consists of four sub-pixels 10, and colors of the four sub-pixels 10 are respectively red (R), green (G), blue (B), and white (W). The white sub-pixel mainly plays the role of adjusting the brightness of the pixel unit.

As can be seen from FIGS. 1 and 2, sub-pixels 10 arranged in the array are not closely arranged to one another, and each gap formed between the sub-pixels 10 is filled with a black matrix (BM) 20 for preventing light leakage and avoiding interference with the colors of adjacent sub-pixels. With the current requirement for resolution of OLED display devices getting higher and higher, sub-pixels are arranged more densely, but due to process constraints, the width of the black matrix cannot be reduced, resulting in the technical problem that the OLED display has a low aperture ratio.

### SUMMARY OF THE INVENTION

The present disclosure is to provide a pixel unit and a display device so as to solve the technical problem that the prior OLED display devices have a low aperture ratio.

The present disclosure provides a pixel unit comprising two sub-pixels of different colors. Each of the sub-pixels is in a regular hexagon shape, and the two of the sub-pixels share one side.

Preferably, the colors of the two sub-pixels are red and green respectively, or the colors of the two sub-pixels are blue and white respectively, or the colors of the two sub-pixels are red and white respectively, or the colors of the two sub-pixels are blue and green respectively.

The present disclosure further provides a display device comprising two types of pixel units as described above. The two types of pixel units include sub-pixels of four different colors of red, green, blue, and white.

Further, colors of two sub-pixels in one type of pixel unit are red and green, and colors of two sub-pixels in the other type of pixel unit are blue and white, or colors of two sub-pixels in one type of pixel unit are red and white, and colors of two sub-pixels in the other type of pixel unit are blue and green.

Preferably, the two sub-pixels in all pixel units are arranged in a same direction.

In one embodiment, in an arrangement direction of two sub-pixels in one pixel unit, sub-pixels of two adjacent pixel units have different colors.

Further, in a column direction extending along data lines, sub-pixels in a same column have a same color and are controlled by a same data line.

In the other embodiment, in the arrangement direction of two sub-pixels in one pixel unit, two adjacent pixel units have sub-pixels of a same color.

Further, in a column direction extending along the data lines, a same column includes two types of sub-pixels of different colors that are alternately arranged, and are controlled by two data lines, respectively.

Preferably, the display device is an organic light emitting diode display device.

The present disclosure provides the following beneficial effects. The pixel unit provided by the disclosure consists of two sub-pixels in a regular hexagon shape, and the display device provided by the disclosure includes the above pixel unit and comprises four sub-pixels of different colors. Since the shape of each sub-pixel is a regular hexagon, a plurality of sub-pixels can be arranged in a honeycomb arrangement in a display area of the display device. With the number of sub-pixels being the same, regular hexagon shaped sub-pixels in a honeycomb arrangement can reduce a total length of a black matrix, so that an area of the black matrix is reduced in the case where a width of the black matrix is constant, and thus the aperture ratio of the display device is improved, which solves the technical problem of low aperture ratio in the prior art.

Other features and advantages of the present disclosure will be further explained in the following description, and partially become self-evident therefrom, or be understood through the embodiments of the present disclosure. The objectives and advantages of the present disclosure will be achieved through the structure specifically pointed out in the description, claims, and the accompanying drawings.

### BRIEF DESCRIPTION OF THE DRAWINGS

The drawings necessary for explaining the embodiments are introduced briefly below to illustrate the technical solutions of the embodiments of the present disclosure more clearly.

FIG. 1 schematically shows a pixel arrangement of an existing OLED display device;

FIG. 2 schematically shows a pixel arrangement of another existing OLED display device;

FIG. 3 schematically shows a pixel unit provided in accordance with embodiment 1 of the present disclosure;

FIG. 4 schematically shows a pixel unit arrangement in a display device provided in accordance with embodiment 2 of the present disclosure:

FIG. 5 schematically shows driving of the pixel units in the display device provided in accordance with embodiment 2 of the present disclosure;

FIG. 6 schematically shows a pixel unit arrangement in a display device provided in accordance with embodiment 3 of the present disclosure; and

FIG. 7 schematically shows driving of pixel units in the display device provided in accordance with embodiment 3 of the present disclosure.

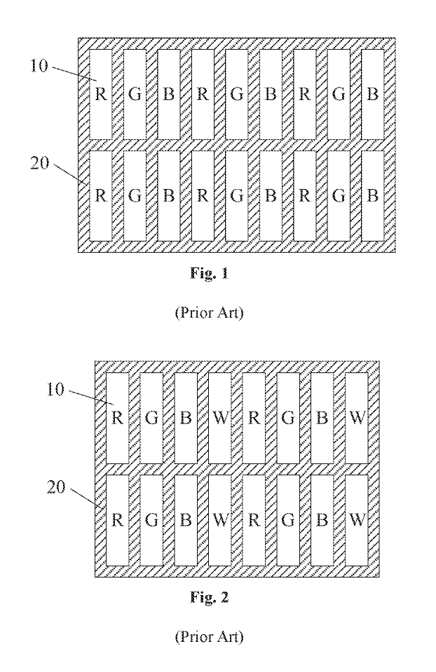

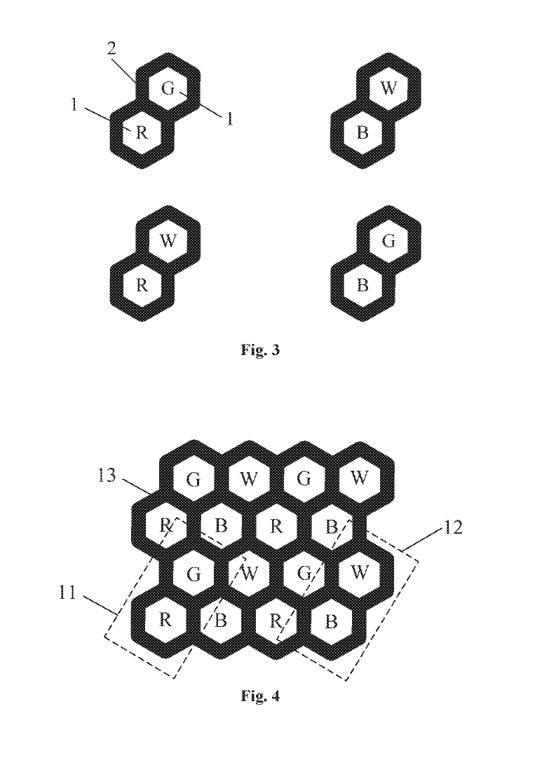

### DETAILED DESCRIPTION OF THE EMBODIMENTS

The embodiments of the present disclosure will be described in detail with reference to the accompanying drawings and examples, and how the technical solutions of the present disclosure can be applied to solve the technical problems and the realization of the technical effects can be fully understood and implemented. It is to be noted that the various embodiments of the present disclosure and the various features in the embodiments may be combined with each other as long as they do not constitute a conflict, and the technical solutions are within the scope of the present disclosure.

### Embodiment 1

As is shown in FIG. 3, a pixel unit provided by the embodiment of the present disclosure comprises two sub-pixels 1 of different colors. Each sub-pixel 1 is in a regular hexagon shape, and the two sub-pixels 1 share one side, i.e., two sides of the two sub-pixels 1 are adjacent to each other.

Colors of the two sub-pixels are preferably four combinations shown in FIG. 3. The colors of the two sub-pixels are red and green, or blue and white, or red and white, or blue and green, respectively. In addition, a black matrix 2 is formed around each sub-pixel.

Each sub-pixel provided by the embodiment of the present disclosure is in a regular hexagon shape; therefore, a plurality of the sub-pixels can be arranged in a honeycomb arrangement. With the number of sub-pixels being the same, regular hexagon shaped sub-pixels in a honeycomb arrangement can reduce a total length of the black matrix, so that an area of the black matrix is reduced in the case where a width of the black matrix is constant, and thus the aperture ratio of the display device is improved, which solves the technical problem of low aperture ratio in the prior art.

### Embodiment 2

The embodiment of the present disclosure provides a display device, preferably an OLED display device. The display device comprises two types of pixel units provided in the above described embodiment 1, and the two types of pixel units include sub-pixels of four different colors of red, green, blue, and white.

As is shown in FIG. 4, in the present embodiment, colors of two sub-pixels in one type of pixel units 11 are red and green, and colors of two sub-pixels in the other type of pixel units 12 are blue and white. The two sub-pixels in all of the pixel units 11 and 12 are arranged in a same direction. As can be seen from FIG. 4, the two sub-pixels in each of the pixel units 11 and 12 are arranged at an angle of 30° with respect to a vertical direction along a direction from lower-left to upper-right.

In the present embodiment, in an arrangement direction of the two sub-pixels of the pixel units 11 and 12. i.e., in the direction of 30° clockwise with respect to the vertical direction, sub-pixels of two adjacent pixel units have different colors. That is, the two pixel units 11, 12 are arranged alternately in the direction, and the sub-pixels are arranged in a honeycomb arrangement. With the number of sub-pixels being the same, the hexagonal sub-pixels arranged in a honeycomb arrangement can reduce a total length of a black matrix 13, so that an area of the black matrix 13 is reduced in the case where a width of the black matrix 13 is constant, and thus the aperture ratio of the display device is improved, which solves the technical problem of low aperture ratio in the prior art.

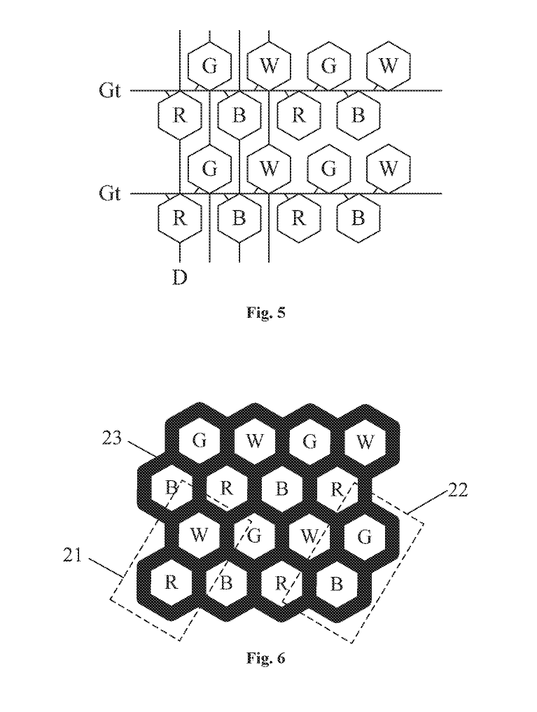

As is shown in FIG. 5, in a column direction (the vertical direction in the figure) extending along a data line D, colors of sub-pixels in a same column are the same, and sub-pixels in a same column are controlled by a same data line D. Controlling of sub-pixels with a same color by a same data line D facilitates generation and output of a data signal. On the other hand, a scanning line Gt for driving respective pixel units is provided between two rows of sub-pixels, and one scanning line Gt can control two rows of sub-pixels, so that the number of scanning lines can be reduced in the embodiment of the present disclosure.

In the display device provided by the embodiment of the present disclosure, two types of pixel units are used, and each type of pixel units each have two sub-pixels of different colors, which together form a display area of four colors: red, green, blue, and white. This is more conducive to perform Pentile algorithm during display, i.e., a pixel unit will borrow another color from its adjacent pixel unit, to constitute the three primary colors, thereby enhancing the display device's virtual resolution, and reducing the manufacturing difficulty of the display device.

It should be noted that the technical solutions provided by the present embodiment are not limited to be used in OLED display devices, and they also can be used in other types of display devices such as liquid crystal display devices.

### Embodiment 3

The embodiment of the present disclosure provides a display device, preferably an OLED display device. The display device comprises two types of pixel units provided in the above described embodiment 1, and the two types of pixel units include sub-pixels of four different colors of red, green, blue, and white.

As is shown in FIG. 6, in the present embodiment, colors of two sub-pixels in one type of pixel unit 21 are red and white, and colors of two sub-pixels in the other type of pixel unit 22 are blue and green. The two sub-pixels in all of the pixel units 21 and 22 are arranged in a same direction. As can be seen from FIG. 4, the two sub-pixels in each pixel unit 21 and 22 are arranged at an angle of 30° with respect to a vertical direction along a direction from lower-left to upper-right.

In the present embodiment, in an arrangement direction of the two sub-pixels in the pixel unit 11 and 12, i.e., in the direction of 30° clockwise with respect to the vertical direction, sub-pixels of two adjacent pixel units have same colors. That is, a same type of pixel units, either the pixel units 21 or the pixel units 22 are arranged in this direction, and the sub-pixels are arranged in a honeycomb arrangement. With the number of sub-pixels being the same, regular hexagon shaped sub-pixels in a honeycomb arrangement can reduce a total length of a black matrix 23, so that an area of the black matrix 23 is reduced in the case where a width of the black matrix 23 is constant, and thus the aperture ratio of the display device is improved, which solves the technical problem of low aperture ratio in the prior art.

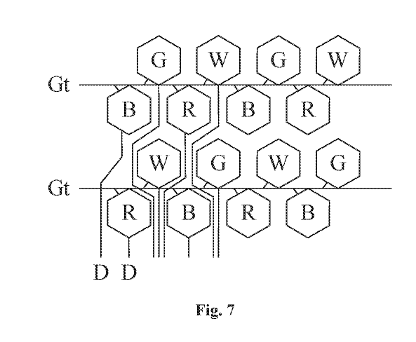

As is shown in FIG. 7, in a column direction (vertical direction in the drawing) extending along a data line D, a same column includes two types of sub-pixels with two different colors that are alternately arranged, and the sub-pixels of the two colors in a same column are controlled by two data lines D respectively. That is, the two types of sub-pixels in a same column are controlled by two data lines D, respectively. Controlling of sub-pixels with same colors by same data lines D can facilitate generation and output of a data signal. On the other hand, a scanning line Gt for driving respective pixel units is provided between two rows of sub-pixels, and one scanning line Gt can control two rows of sub-pixels, so that a number of scanning lines can be reduced in the embodiment of the present disclosure.

In the display device provided by the embodiment of the present disclosure, two types of pixel units are used, and each type of pixel units each have two sub-pixels of different colors, which together form a display area of four colors: red, green, blue, and white. This is more conducive to perform Pentile algorithm during display, i.e., a pixel unit will borrow another color from its adjacent pixel unit, to constitute the three primary colors, thereby enhancing the display device's virtual resolution, and reducing the manufacturing difficulty of the display device.

It should be noted that the technical solutions provided by the present embodiment are not limited to be used in OLED display devices, and they also can be used in other types of display devices such as liquid crystal display devices.

The above embodiments are described only for better understanding, rather than restricting the present disclosure. Any person skilled in the art can make amendments to the implementing forms or details without departing from the spirit and scope of the present disclosure. The protection scope of the present disclosure shall be determined by the scope as defined in the claims.

1. A pixel unit, comprising two sub-pixels of different colors, wherein each of the sub-pixels is in a regular hexagon shape, and the two sub-pixels share one side.

2. The pixel unit according to claim 1, wherein:
colors of the two sub-pixels are red and green, respectively, or
colors of the two sub-pixels are blue and white, respectively, or
colors of the two sub-pixels are red and white, respectively, or
colors of the two sub-pixels are blue and green, respectively.

3. A display device, comprising two types of pixel units,
wherein each type of pixel unit includes two sub-pixels of different colors,
wherein each of the sub-pixels is in a regular hexagon shape, and the two sub-pixels share one side, and
wherein the two types of pixel units include sub-pixels of four different colors of red, green, blue, and white.

4. The display device according to claim 3, wherein:
colors of two sub-pixels in one type of pixel unit are red and green, and colors of two sub-pixels in the other type of pixel unit are blue and white, or
colors of two sub-pixels in one type of pixel unit are red and white, and colors of two sub-pixels in the other type of pixel unit are blue and green.

5. The display device according to claim 3, wherein, two sub-pixels in all pixel units are arranged in a same direction.

6. The display device according to claim 4, wherein, two sub-pixels in all pixel units are arranged in a same direction.

7. The display device according to claim 5, wherein, in an arrangement direction of two sub-pixels in one pixel unit, sub-pixels of two adjacent pixel units have different colors.

8. The display device according to claim 6, wherein, in an arrangement direction of two sub-pixels in one pixel unit, sub-pixels of two adjacent pixel units have different colors.

9. The display device according to claim 7, wherein, in a column direction extending along data lines, sub-pixels in a same column have a same color and are controlled by a same data line.

10. The display device according to claim 8, wherein, in a column direction extending along data lines, sub-pixels in a same column have a same color and are controlled by a same data line.

11. The display device according to claim 5, wherein, in the arrangement direction of two sub-pixels in one pixel unit, two adjacent pixel units have sub-pixels of a same color.

12. The display device according to claim 6, wherein, in the arrangement direction of two sub-pixels in one pixel unit, two adjacent pixel units have sub-pixels of a same color.

13. The display device according to claim 11, wherein, in the column direction extending along the data lines, a same column includes two types of sub-pixels of different colors that are alternately arranged and are controlled by two data lines, respectively.

14. The display device according to claim 12, wherein, in the column direction extending along the data lines, a same column includes two types of sub-pixels of different colors that are alternately arranged and are controlled by two data lines, respectively.

15. The display device according to claim 3, wherein the display device is an organic light emitting display device.

16. The display device according to claim 4, wherein the display device is an organic light emitting display device.
